(19) United States
(12) Patent Application Publication
(10) Pub. No.: US 2004/0124528 A1
(43) Pub. Date: Jul. 1, 2004

(54) Metal line structures in semiconductor devices and methods of forming the same

(76) Inventor: Jae Suk Lee, Seoul (KR)

Correspondence Address: GROSSMAN & FLIGHT LLC, Suite 4220, 20 North Wacker Drive, Chicago, IL, 60606-6357, US

(21) Appl. No.: 10/712,945

(22) Filed: Nov. 13, 2003

(30) Foreign Application Priority Data
Dec. 30, 2002 (KR) 10-2002-0086218

(51) Int. Cl. H01L 23/48

(52) U.S. Cl. 257/734

(57) ABSTRACT

Metal line structures in semiconductor devices and methods of forming the same are disclosed. A disclosed method for forming a metal line structure on a substrate includes: forming first metal lines, the first metal lines having a first barrier metal layer and a first conductive layer; forming a first interlayer insulator on the substrate and the first metal lines; planarizing the first interlayer insulator by removing a part of the first interlayer insulator to expose a top surfaces of the first metal lines; forming a second interlayer insulator on the first interlayer insulator and the first metal lines; selectively etching the second interlayer insulator to expose top surfaces of the first metal lines; sequentially forming a second barrier metal layer and a second conductive layer on the etched second interlayer insulator and the first metal lines; and planarizing the second conductive layer and the second barrier metal layer to expose top surfaces of the second interlayer insulator, thereby forming second metal lines comprising a portion of the second barrier metal layer and a portion of the second conductive layer.

### FIELD OF THE DISCLOSURE

This disclosure relates generally to semiconductor devices, and, more particularly, to metal line structures in semiconductor devices and methods of forming the same.

### BACKGROUND

As shown in FIG. 1A, a conventional method for forming a metal line sequentially stacks a first Ti/TiN layer 13, a metal layer 15 and a second Ti/TiN layer 17 on a substrate 11. Al is generally used as the metal layer 15.

Referring to FIG. 1B, a photoresist film is coated on the second Ti/TiN layer 17, and a photoresist pattern 19 is formed by selectively exposing and developing the photoresist film such that a pattern of the photoresist film is left in the areas intended to form metal lines. Such a process is referred to as an embossed patterning method.

Referring to FIG. 1C, by selectively etching the first Ti/TiN layer 13, the metal layer 15, and the second Ti/TiN layer 17 by using the photoresist pattern 19 as a mask, metal line(s) having a stacked structure including the Ti/TiN layer 13, the metal layer 15 and the Ti/TiN layer 17 is formed. The photoresist pattern 19 is then removed.

Recently, as semiconductor devices have become more highly integrated, in order to form a metal line having low resistance, a thickness of the metal line is increased. Further, a pitch of adjacent metal lines is decreased, thereby causing difficulty in forming an interlayer insulator. For resolving such problems, a damascene process using Cu instead of Al as the metal line is employed.

However, the damascene process using Cu has many problems because a plating process should be performed therein for mass production. Also, if a metal line including Cu is formed on the substrate, a problem occurs wherein Cu ions are diffused on the substrate.

### BRIEF DESCRIPTION OF THE DRAWINGS

FIGS. 1A to 1C illustrate cross sectional views sequentially showing a conventional method of forming a metal line.

FIGS. 2A to 2I depict cross sectional views sequentially showing an example method of forming a metal line.

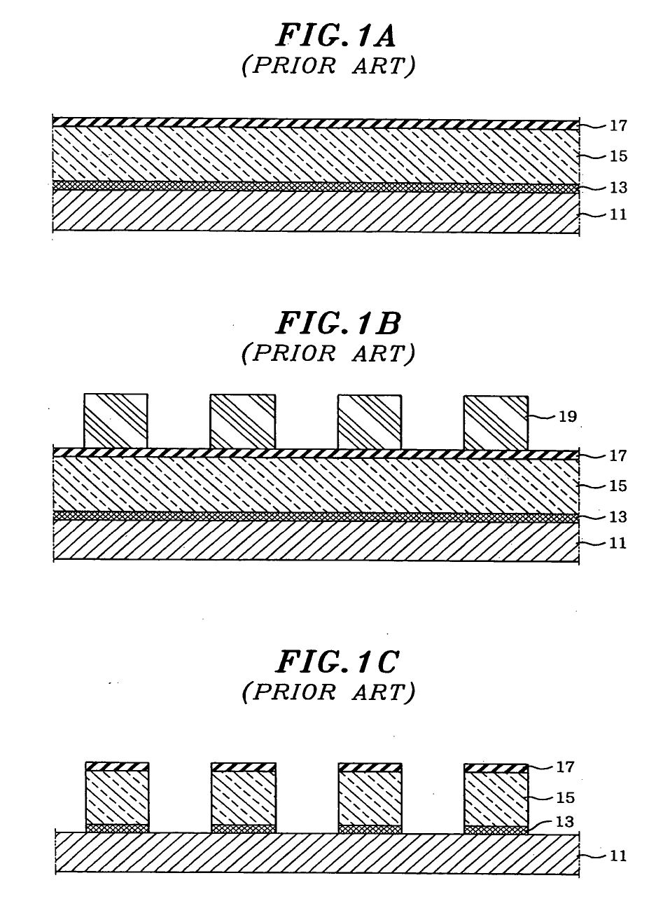

Like reference numerals used in the drawings refer to like parts.

### DETAILED DESCRIPTION

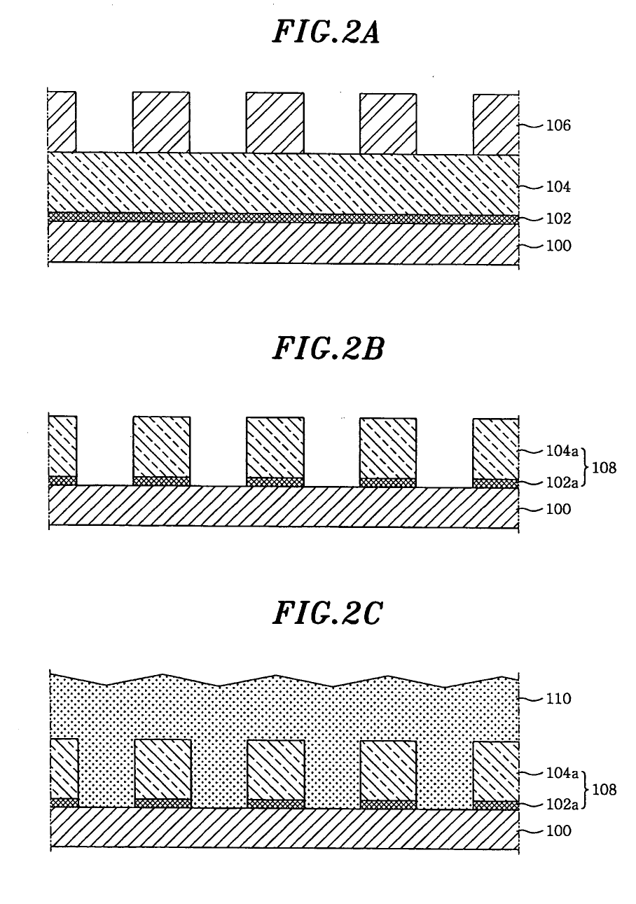

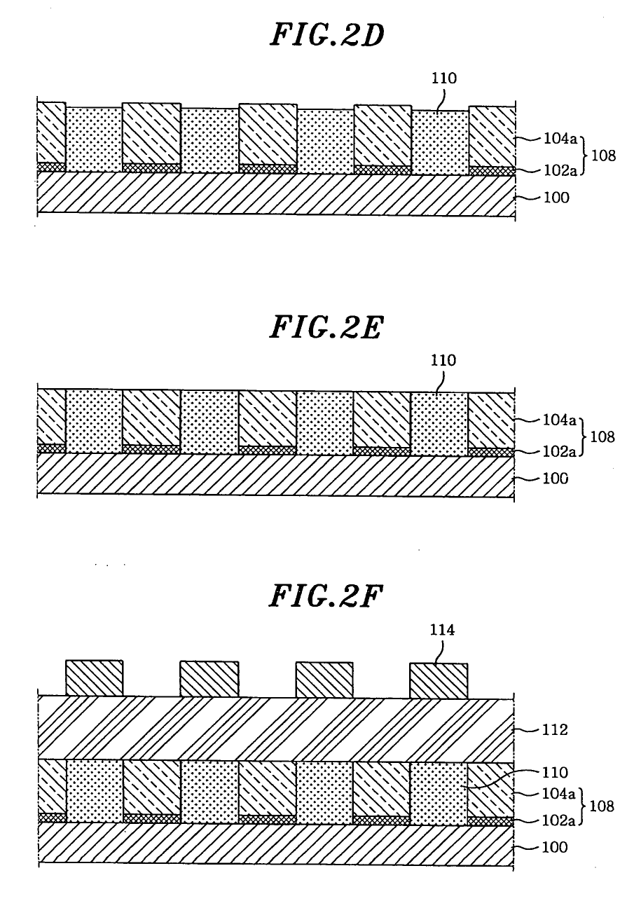

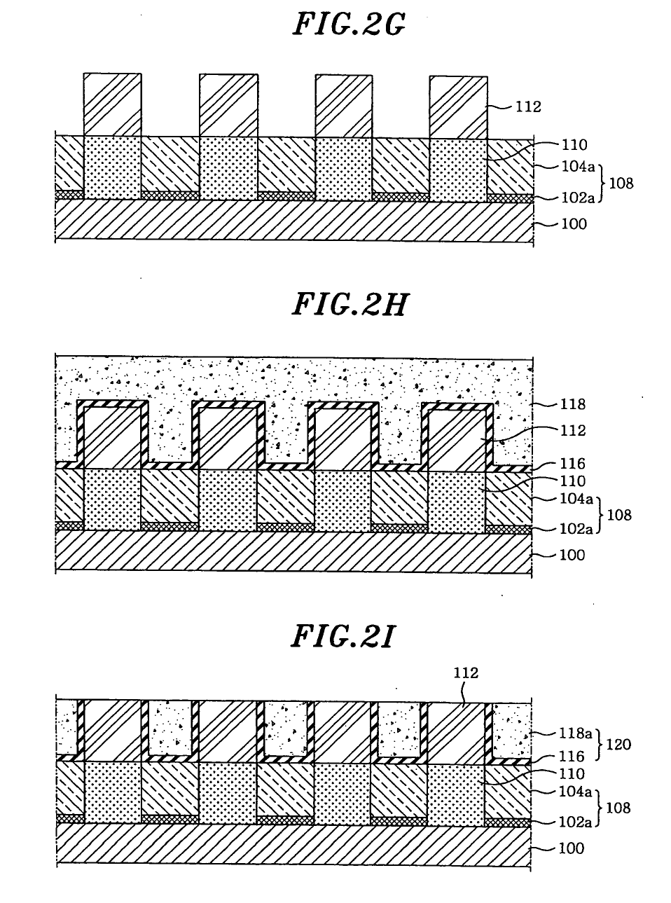

FIGS. 2A to 2I are cross sectional views showing an example process of forming a metal line in a semiconductor device. The structure of the metal line formed by the process illustrated in FIGS. 2A-2I includes first metal lines 108 (each having a first barrier metal layer 102a and a first conductive layer 104a); a first interlayer insulator 110 filled between the adjacent first metal lines 108; second metal lines 120 (each having a second barrier metal layer 116 and a second conductive layer 118a); and a second interlayer insulator filled between the adjacent second metal lines, wherein the second metal lines 120 are formed on respective ones of the first metal lines 108.

Referring to FIG. 2A, the first barrier metal layer 102 and the first conductive layer 104 is sequentially stacked on an insulating substrate 100 having metal line contact holes (not shown). A photoresist film is then coated on the first conductive layer 104. A first photoresist pattern 106 is then formed by an embossed patterning method wherein the photoresist film is removed everywhere except in those areas where it is desired to form the first metal lines. In this process, an Al alloy containing 5% or less Cu is used as the first conductive layer 104 and each of the deposited first metal lines 108 has about 50% of the thickness of a desired metal line structure.

As shown in FIG. 2B, the first conductive layer 104 and the first barrier metal layer 102 are selectively etched by using the photoresist pattern 106 as a mask, so that the first metal lines 108 are formed with each of the first metal lines 108 including the patterned first barrier metal layer 102a and the patterned first conductive layer 104a. The photoresist pattern 106 is then removed. (see FIG. 2B)

Referring to FIG. 2C, by using, for example, an HDP (High Density Plasma) process, a first interlayer insulator 110 is formed on the entire substrate 100 and the first metal lines 108 formed on the substrate 100. At this time, because the thickness of each of the first metal lines 108 is small, no void is generated inside of the interlayer insulator 110 and no clipping occurs at the top corners of the first metal lines 108. The first interlayer insulator 110 formed on the entire substrate may be USG (Undoped Silicate Glass) or FSG (Fluorinated Silicate Glass) deposited by the HDP process.

As shown in FIG. 2D, by performing a CMP (Chemical Mechanical Polishing) process, an upper part of the first interlayer insulator 110 is removed to expose the top surface of each of the first metal lines 108. In the CMP process, the thickness of the first interlayer insulator 110 becomes less than that of the first metal lines 108, which is a cause of a metal bridge.

As shown by comparing FIGS. 2D and 2E, a metal CMP process is performed in order to eliminate the cause of the metal bridge. By the metal CMP process, a part of each of the first metal lines 108 is removed so as to have the same thickness as the first interlayer insulator 110. As a result, the first metal lines 108 and the first interlayer insulator 110 are evenly flattened.

Thereafter, as shown in FIG. 2F, a second interlayer insulator 112 is formed on the first metal lines 108 and the first interlayer insulator 110 by performing a PECVD (Plasma Enhanced Chemical Vapor Deposition) process. A photoresist film is coated on the second interlayer insulator 112. The photoresist film is then patterned to expose only areas above the first metal lines 108 to create, a second photoresist pattern 114. At this time, USG or FSG deposited by the PECVD process or PECVD SiOC (Silicon Oxycarbide) is used as the second interlayer insulator 112. The second interlayer insulator 112 has about 50% of the thickness of the desired metal line structure.

As shown in FIG. 2G, the second interlayer insulator 112 is selectively etched by using the photoresist pattern 114 as a mask until the top surface of each of the first metal lines 108 is entirely exposed. The photoresist pattern 114 is then removed.

Referring to FIG. 2H, a second barrier metal layer 116 is formed on the etched second interlayer insulator 112. A second conductive layer 118 is then formed on the second barrier metal layer 116, such that the spaces above the first metal lines 108 are filled with the second conductive layer 118. At this time, for example, Cu having a low resistance is used as the second conductive layer 118.

As shown in FIG. 21, the second conductive layer 118 and the second barrier metal layer 116 are removed and planarized by the metal CMP process to expose the top surface of the second interlayer insulator 112. In this way, second metal lines 120 are formed. Each of the second metal lines 120 includes the second barrier metal layer 116 and the planarized second conductive layer 118a. Therefore, a hybrid metal line having a stacked structure of the first barrier metal layer 102a, the first conductive layer 104a, the second barrier metal layer 116 and the second conductive metal layer 118a is obtained.

Any one of Ti, TiN, Ta, TaN, W, WN and/or a combination thereof may be used as the first and/or the second barrier metal layer 102a, 116.

Since the hybrid metal line(s) have a stacked structure of an Al alloy and Cu, the metal line(s) have low resistance. Further the Cu portion of the metal line(s) is formed separated from the substrate 100, thereby preventing Cu ions from being diffused into the substrate.

From the foregoing, persons of ordinary skill in the art will appreciate that the above disclosed methods and apparatus provide a metal line in a semiconductor device and a method for forming the same, wherein the metal line has low resistance and prevents Cu ions from being diffused into the substrate.

From the foregoing, persons of ordinary skill in the art will further appreciate that methods for forming a metal line structure on a substrate have been disclosed. A disclosed method includes: forming first metal lines, each having a first barrier metal layer and a first conductive layer; forming a first interlayer insulator on the substrate and the first metal lines; planarizing the first interlayer insulator by removing a part of the interlayer insulator to expose a top surface of each of the first metal lines; forming a second interlayer insulator on the first interlayer insulator and the first metal lines; selectively etching the second interlayer insulator to expose the top surface of each of the first metal lines; forming a second barrier metal layer and a second conductive layer sequentially on the etched second interlayer insulator and the first metal lines; and planarizing the second conductive layer and the second barrier metal layer to expose a top surface of the second interlayer insulator, thereby forming second metal lines each having the second barrier metal layer and the second conductive layer.

Persons of ordinary skill in the art will further appreciate that, metal line structures formed in a semiconductor device have been disclosed. A disclosed metal line structure includes: first metal lines, each having a first barrier metal layer and a first conductive layer formed on a substrate; a first interlayer insulator filled between the adjacent first metal lines; second metal lines, each having a second barrier metal layer and a second conductive layer, the second metal lines being respectively formed on the first metal lines; and a second interlayer insulator filled up between the adjacent second metal lines.

Although certain example methods and apparatus have been described herein, the scope of coverage of this patent is not limited thereto. On the contrary, this patent covers all methods, apparatus and articles of manufacture fairly falling within the scope of the appended claims either literally or under the doctrine of equivalents.

What is claimed is:

1. A method to form a metal line structure on a substrate comprising:
forming first metal lines, the first metal lines having a first barrier metal layer and a first conductive layer;
forming a first interlayer insulator on the substrate and the first metal lines;
planarizing the first interlayer insulator by removing a part of the first interlayer insulator to expose a top surfaces of the first metal lines;
forming a second interlayer insulator on the first interlayer insulator and the first metal lines;
selectively etching the second interlayer insulator to expose top surfaces of the first metal lines;
sequentially forming a second barrier metal layer and a second conductive layer on the etched second interlayer insulator and the first metal lines; and
planarizing the second conductive layer and the second barrier metal layer to expose top surfaces of the second interlayer insulator, thereby forming second metal lines comprising a portion of the second barrier metal layer and a portion of the second conductive layer.

2. A method as defined in claim 1, wherein each of the first metal lines has about 50% of a desired thickness of a desired metal line structure.

3. A method as defined in claim 2, wherein the first metal lines comprise an Al alloy containing about 5% or less Cu.

4. A method as defined in claim 1, wherein a portion of each of the first metal line protruding from the first interlayer insulator is removed, after planarizing the first interlayer insulator.

5. A method as defined in claim 1, wherein the planarizing is performed by a CMP process.

6. A method as defined in claim 1, wherein the second interlayer insulator has about 50% of a desired thickness of a desired metal line structure.

7. A method as defined in claim 1, wherein the second conductive layer comprises Cu.

8. A method as defined in claim 1, wherein the first interlayer insulator is made of USG or FSG deposited by an HDP process.

9. A method as defined in claim 1, wherein the second interlayer insulator is made of USG or FSG deposited by a PECVD process.

10. A method as defined in claim 1, wherein the second interlayer insulator is made of USG or FSG deposited by PECVD SiOC.

11. A method as defined in claim 1, wherein the first and the second barrier metal layers comprise at least one of Ti, TiN, Ta, TaN, W and WN.

12. A metal line structure formed in a semiconductor device, comprising:
first metal lines formed on a substrate, the first metal lines having a first barrier metal layer and a first conductive layer;
a first interlayer insulator between adjacent ones of the first metal lines;
second metal lines formed on respective ones of the first metal lines, the second metal lines having a second barrier metal layer and a second conductive layer; and
a second interlayer insulator between adjacent ones of the second metal lines.

13. A metal line structure as defined in claim 12, wherein each of the first metal lines has about 50% of a desired thickness of the metal line structure.

14. A metal line structure as defined in claim 12, wherein the first metal lines comprises an Al alloy containing 5% or less.

15. A metal line structure as defined in claim 12, wherein the second interlayer insulator has about 50% of a desired thickness of the desired metal line structure.

16. A metal line structure as defined in claim 12, wherein the second conductive layer comprises Cu.

17. A metal line structure as defined in claim 12, wherein the first interlayer insulator is made of USG or FSG deposited by an HDP process.

18. A metal line structure as defined in claim 12, wherein the second interlayer insulator is made of USG or FSG deposited by a PECVD process.

19. A metal line structure as defined in claim 12, wherein the second interlayer insulator is made of USG or FSG deposited by a PECVD SiOC.

20. A metal line structure as defined in claim 12, wherein the first and the second barrier metal layers comprise at least one of Ti, TiN, Ta, TaN, W and WN.
